(19) United States
(12) Patent Application Publication
(10) Pub. No.: US 2012/0097251 A1
(43) Pub. Date: Apr. 26, 2012

(54) PHOTOELECTRIC CONVERSION DEVICE METHOD FOR MAKING SAME AND ELECTRONIC DEVICE

(76) Inventors: Harumi Takada, Kanagawa (JP); Masaki Orihashi, Kanagawa (JP); Reiko Yonaya, Kanagawa (JP); Masahiro Morooka, Kanagawa (JP); Yusuke Isshiki, Kanagawa (JP); Yusuke Suzuki, Kanagawa (JP)

(21) Appl. No.: 13/061,320

(22) PCT Filed: Jun. 25, 2010
(86) PCT No.: PCT/JP2010/061302

§ 371 Date: Feb. 28, 2011

(30) Foreign Application Priority Data
Jul. 1, 2009 (JP) 2009-156915

(51) Int. Cl. H01L 51/46; H01L 31/18; B82Y 99/00

(52) U.S. Cl. 136/263; 438/85; 977/948; 257/E31.124

(57) ABSTRACT

A photoelectric conversion device and a method for making same are provided wherein a porous photoelectrode is prevented from dissolution in an electrolyte, a surface plasmon resonance effect can be well obtained, and a drastic improvement in photoelectric conversion efficiency can be attained.

In a photoelectric conversion device having a structure wherein an electrolyte layer (6) is filled between a porous photoelectrode (3) formed on a transparent substrate (1) and a counter electrode (4), the porous photoelectrode (3) is constituted of metal/metal oxide fine particles (7) including a core made of a metal and a shell surrounding the core and made of a metal oxide. In a dye-sensitized photoelectric conversion device, a sensitizing dye (8) is adsorbed on the surface of the porous photoelectrode (3).

### TECHNICAL FIELD

This invention relates to a photoelectric conversion device and a method for making same, and also to an electronic device. The invention relates to a photoelectric conversion device adapted for use, for example, in dye-sensitized solar cells and a method for making same, and an electronic device making use of this photoelectric conversion device.

### BACKGROUND ART

In recent years, dye-sensitized solar cells for use as a next-generation solar cell to be used as a substitute for silicon (Si) solar cells have been widely studied (see, for example, Non-patent Document 1). Since the dye-sensitized solar cell is more inexpensive than silicon solar cells and is simple in manufacturing process, the practical application thereof has been expected. In general, however, dye-sensitized solar cells are not higher in photoelectric conversion efficiency than crystalline silicon solar cells.

To cope with this, several studies have been made in order to aim at performance improvement of the dye-sensitized solar cells. The first mention is made of a technique wherein semiconductor fine particles forming a photoelectrode are nanosized so as to increase the specific surface area. This enables a photosensitizer, which is to be adsorbed on the surface of the semiconductor particles, to be increased in amount, thereby leading to an improved photoelectric conversion efficiency. The second mention is made of a method of improving the photoelectric conversion efficiency by confining light entering into a porous membrane constituting a photoelectrode of a dye-sensitized solar cell. The third mention is made of a method of improving the absorption coefficient of photosensitizers.

For the method of improving the absorption coefficient of photosensitizers, mention is made of a method making use of a field reinforcing effect based on local surface plasmon. It is known that in dye-sensitized solar cells, if fine particles of a metal such as gold, silver or copper is used, the field reinforcing effect ascribed to a local surface plasmon is obtained (see Patent Document 1, for example). A surface plasmon is excited on a metal surface, whereupon there is generated an electric field that is spacially localized in the vicinity of the metal surface and is reinforced to several tens to several hundreds of times greater than that of incident light. When a semiconductor light-receiving layer is placed in the vicinity of the metal surface excited with the surface plasmon, carriers can be excited in great quantity by the action of the reinforced field, thus enabling the photoelectric conversion efficiency to be enhanced. An attempt has been made wherein in a laminate structure of fine particles made of metal fine particles and semiconductor fine particles, a local surface plasmon resonance is reinforced through the mutual interaction of the metal fine particles regularly arranged, under which the absorption coefficient of a photosensitizer adsorbed on the metal fine particles is improved (see Patent Document 2).

Further, investigations of dye-sensitized solar cells have been made, in which in an anode electrode having a dye, such as a ruthenium complex, supported on the film surface of a metal oxide such as titanium oxide, fine particles of a metal such as platinum, a platinum alloy, palladium or a palladium alloy are provided in the vicinity of the dye (see Patent Document 3).

It will be noted that charge separation and catalytic ability of an Ag/TiO₂ core-shell complex cluster under irradiation of UV light has been reported (see Non-patent Document 2).

### PRIOR ART DOCUMENTS

### Non-Patent Document

Non-patent Document 1: Nature, 353, pp. 737-740, 1991

Non-patent Document 2: J. AM. Chem. Soc. 2005, 127, 3928-3934

Non-patent Document 3: Jpn. J. Appl. Phys. Vol. 46, No. 4B, 2007, pp. 2567-2570

### Patent Document

Patent Document 1: Japanese Patent Laid-open No. Hei 9-259943

Patent Document 2: Japanese Patent Laid-open No. 2007-335222

Patent Document 3: Japanese Patent Laid-open No. 2001-35551

### SUMMARY OF INVENTION

However, it is known that fine particles made of gold, silver, copper or the like, which exhibits a great surface plasmon resonance effect, is dissolved in iodine-based electrolytic solutions. Hence, it has been necessary to use electrolytes other than iodine-based ones. However, in dye-sensitized solar cells making use of electrolytes other than iodine, a high photoelectric conversion efficiency has never been obtained. Although a method making use of metals other than gold, silver and copper has been studied so as to prevent dissolution with iodine as proposed in Patent Document 3, a satisfactory surface plasmon resonance effect cannot be obtained when using fine particles such as of platinum.

Accordingly, a problem to be solved by the invention is to provide a photoelectric conversion device, which is able to prevent dissolution of a porous photoelectrode with an electrolyte and in which a surface plasmon resonance effect can be well obtained and the photoelectric conversion efficiency can be drastically improved, and also a method for making same.

Other problem to be solved by the invention is to provide a high-performance electronic device making use of such an excellent photoelectric conversion device.

In order to solve the above problems, the invention provides a photoelectric conversion device, which includes a porous photoelectrode constituted of fine particles composed of a core made of a metal and a shell surrounding the core and made of a metal oxide.

The invention also provides a method for making a photoelectric conversion device, which includes the step of forming a porous photoelectrode by use of fine particles including a core made of a metal and a shell surrounding the core and made of a metal oxide.

The invention further provides an electronic device including a photoelectric conversion device having a porous electrode, which is constituted of fine particles including a core made of a metal and a shell surrounding the core and made of a metal oxide.

In the practice of the invention, as the metal for the core of the fine particles forming the porous photoelectrode, there are used metals having a great surface plasmon resonance effect, which are chosen as necessary. As such a metal, there is preferably used at least one metal selected from the group including gold (Au), silver (Ag), copper (Cu), platinum (Pt) and palladium (Pd). For the metal oxide constituting the shell of the fine particles used to form a porous photoelectrode, there are used metal oxides that are not dissolved with an electrolyte used, and these metal oxides are chosen as necessary. As such a metal oxide, there is preferably used at least one metal oxide selected from the group including titanium oxide (TiO₂), tin oxide (SnO₂), niobium oxide (Nb₂O₅) and zinc oxide (ZnO) although not limited thereto. For instance, there may be used metal oxides such as tungsten. oxide (WO₃), strontium titanate (SrTiO₃) and the like. The size of the fine particles is appropriately chosen and is preferably at 1 to 500 nm, and the size of the core of the fine particles is also appropriately chosen and is preferably at 1 to 200 nm.

In the invention, where a photoelectric conversion device is constituted for a dye-sensitized photoelectric conversion device, a senisitizing dye is adsorbed on the porous photoelectrode. This dye-sensitized photoelectric conversion device typically has such a structure wherein an electrolyte layer is filled between the porous photoelectrode and a counter electrode and a sensitizing dye is adsorbed on the porous photoelectrode. In order to improve the photoelectric conversion efficiency and durability of the dye-sensitized photoelectric conversion device, it is preferred that the porous photoelectrode is adsorbed with Z907 and dye A as a sensitizing dye and 3-methoxypropionitrile is contained in the electrolyte layer as a solvent. Such a dye-sensitized photoelectric conversion is typically made by a method, which includes the steps of forming a porous photoelectrode, adsorbing Z907 and dye A as a sensitizing dye on the porous photoelectrode, and forming such a structure wherein an electrolyte layer is filled between the porous photoelectrode and a counter electrode wherein 3-methoxypropionitrile is contained in the electrolyte layer as a solvent.

The Z907 and dye A serving as a sensitizing dye typically bind to a metal oxide, which constitutes the shell of the fine particles making up of the porous photoelectrode, through adsorption in different steric configurations. Typically, Z907 has a carboxy group (—COOH) as a functional group to be bound to the metal oxide and dye A has a carboxy group (—COOH) and a cyano group (—CN) bound to the same carbon as functional groups to be bound to the metal oxide.

The electrolyte layer filled between the porous photoelectrode and the counter electrode is typically made of an electrolytic solution or a gel or solid electrolyte. Preferably, the electrolyte layer is made of a nano composite gel made of an electrolytic solution and nanoparticles, and nanoparticles used are typically those made of TiO₂ or SiO₂ although not limited thereto.

The photoelectric conversion device or dye-sensitized photoelectric conversion device may be fabricated in various shapes depending on its use and is not critical with respect to the shape thereof.

Most typically, the photoelectric conversion device or dye-sensitized photoelectric conversion device is formed as a solar cell. In this regard, however, the photoelectric conversion device or dye-sensitized photoelectric conversion device may be provided as one other than solar cells, for example, a photosensor.

The electronic devices may fundamentally take any forms including both portable and desktop types and specific examples include cell phones, mobile devices, robotic systems, personal computers, in-vehicle devices, a variety of domestic electric products and the like. In this case, the photoelectric conversion device or dye-sensitized photoelectric conversion device serves, for example, as a solar cell used as an electric supply of these electronic devices.

In the invention configured as stated above, the porous photoelectrode of a photoelectric conversion device is constituted of fine particles including a core made of a metal and a shell surrounding the core and made of a metal oxide. In doing so, when an electrolyte layer is filled between the porous photoelectrode and a counter electrode, the electrolyte does no contact the core made of a metal. Accordingly, while making use, as a metal forming the core of the fine particle, of gold, silver or copper that has a great surface plasmon resonance effect, an iodine-based electrolyte can be used as an electrolyte.

Especially, in a dye-sensitized photoelectric conversion device, when Z907 and dye A are used as a sensitizing dye to be bound to the porous photoelectrode and 3-methoxypropionitrile is used as a solvent contained in the electrolyte layer, i.e. as a solvent used to prepare the electrolyte layer, it can be suppress to lower a photoelectric conversion efficiency with time.

According to this invention, there can be obtained a photoelectric conversion device that is able to prevent the dissolution of a porous photoelectrode with an electrolyte along with a satisfactory surface plasmon resonance effect being obtained and permits a photoelectric conversion efficiency to be drastically improved. When using this excellent photoelectric conversion device, high-performance electronic devices can be realized.

### BRIEF DESCRIPTION OF DRAWINGS

FIG. 1 is a sectional view showing a dye-sensitized photoelectric conversion device according to a first embodiment of the invention.

FIG. 2 is a sectional view showing a configuration of a metal/metal oxide fine particle constituting a porous photoelectrode in the dye-sensitized photoelectric conversion device according to the first embodiment of the invention.

FIG. 3 is a sectional view showing a dye-sensitized photoelectric conversion device according to a second embodiment of the invention.

FIG. 4 is a sectional view showing a dye-sensitized photoelectric conversion device according to a third embodiment of the invention.

FIG. 5 is a sectional view showing a dye-sensitized photoelectric conversion device according to a fourth embodiment of the invention.

FIG. 6 is a sectional view showing a dye-sensitized photoelectric conversion device according to a fifth embodiment of the invention.

FIG. 7 is a sectional view showing a dye-sensitized photoelectric conversion device according to a sixth embodiment of the invention.

FIG. 8 is a sectional view showing a photoelectric conversion device according to a seventh embodiment of the invention.

FIG. 9 is a sectional view showing a photoelectric conversion device according to an eighth embodiment of the invention.

FIG. 10 is a sectional view showing a photoelectric conversion device according to a ninth embodiment of the invention.

FIG. 11 is a sectional view showing a photoelectric conversion device according to a tenth embodiment of the invention.

FIG. 12 is a sectional view showing a photoelectric conversion device according to an eleventh embodiment of the invention.

FIG. 13 is a sectional view showing a photoelectric conversion device according to a twelfth embodiment of the invention.

FIG. 14 is a diagrammatic view showing a structural formula of Z907 adsorbed, as a sensitizing dye, on a porous photoelectrode in a dye-sensitized photoelectric conversion device according to a thirteenth embodiment of the invention.

FIG. 15 is a diagrammatic view showing the results of measurement of IPCE spectra of a dye-sensitized photoelectric conversion device wherein Z907 is adsorbed singly on a porous TiO₂ photoelectrode.

FIG. 16 is a diagrammatic view showing a structural formula of dye A adsorbed, as a sensitizing dye, on a porous photoelectrode in the dye-sensitized photoelectric conversion device according to the thirteenth embodiment of the invention.

FIG. 17 is a diagrammatic view showing the results of measurement of IPCE spectra of a dye-sensitized photoelectric conversion device wherein dye A is adsorbed singly on a porous TiO₂ photoelectrode.

FIG. 18 is a diagrammatic view showing an operation principle of the dye-sensitized photoelectric conversion device according to the thirteenth embodiment of the invention.

FIG. 19 is a diagrammatic view showing the results of measurement of IPCE spectra of an evaluation device for dye-sensitized photoelectric conversion device according to the thirteenth embodiment of the invention along with the results of measurement of comparative examples.

FIG. 20 is a diagrammatic view showing the results of measurement of a change, with time, of a photoelectric conversion efficiency of an evaluation device of the dye-sensitized photoelectric conversion device according to the thirteenth embodiment of the invention along with the results of measurement of comparative examples.

### MODE FOR CARRYING OUT THE INVENTION

The modes for carrying out the invention (hereinafter referred to as “embodiments”) are illustrated. It will be noted that the illustration is made in the following order.
1. First embodiment (a dye-sensitized photoelectric conversion device and a method for making same)
2. Second embodiment (a dye-sensitized photoelectric conversion device and a method for making same)
3. Third embodiment (a dye-sensitized photoelectric conversion device and a method for making same)
4. Fourth embodiment (a dye-sensitized photoelectric conversion device and a method for making same)
5. Fifth embodiment (a dye-sensitized photoelectric conversion device and a method for making same)
6. Sixth embodiment (a dye-sensitized photoelectric conversion device and a method for making same)
7. Seventh embodiment (a photoelectric conversion device and a method for making same)
8. Eighth embodiment (a photoelectric conversion device and a method for making same)
9. Ninth embodiment (a photoelectric conversion device and a method for making same)
10. Tenth embodiment (a photoelectric conversion device and a method for making same)
11. Eleventh embodiment (a photoelectric conversion device and a method for making same)
12. Twelfth embodiment (a photoelectric conversion device and a method for making same)
13. Thirteenth embodiment (a dye-sensitized photoelectric conversion device and a method for making same)
14. Fourteenth embodiment (a dye-sensitized photoelectric conversion device and a method for making same)

### <1. First Embodiment>

### [Dye-Sensitized Photoelectric Conversion Device]

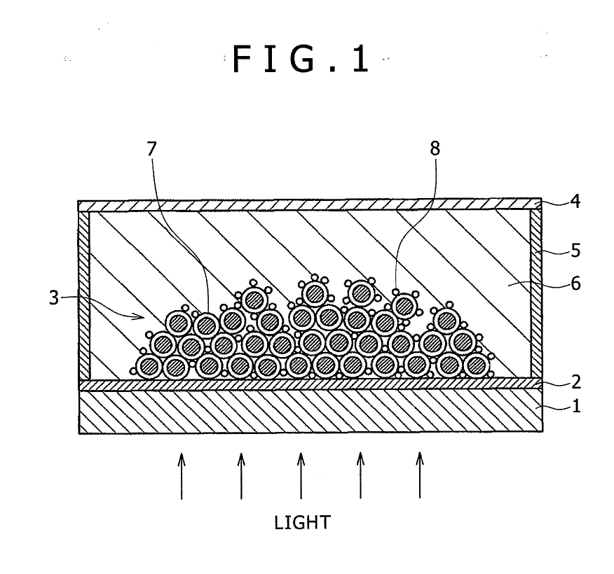

FIG. 1 is a sectional view of an essential part showing a dye-sensitized photoelectric conversion device according to a first embodiment of the invention.

As shown in FIG. 1, in this dye-sensitized photoelectric conversion device, a transparent substrate 1 is provided on its main surface with a transparent conductive film 2, on which a porous photoelectrode 3 adsorbing one or plural types of sensitizing dyes (hereinafter referred to simply as dye) is provided. On the other hand, a counter electrode 4 is provided in face-to-face relation with the transparent substrate 1. These transparent substrate 1 and counter electrode 4 are sealed with a sealant 5 along an outer periphery thereof, and an electrolyte layer 6 is filled between the porous photoelectrode 3 and the counter electrode 4 over the transparent substrate 1.

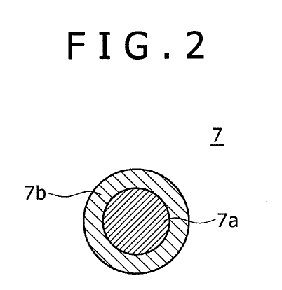

The porous photoelectrode 3 is constituted of metal/metal oxide fine particles 7 and typically, is formed of a sintered product of these metal/metal oxide fine particles 7. The detail of the structure of the metal/metal oxide fine particle 7 is shown in FIG. 2. As shown in FIG. 2, the metal/metal oxide fine particle 7 has a core/shell structure including a spherical core 7a made of a metal and a shell 7b surrounding the core 7a and made of a metal oxide. One or plural types of dyes 8 are adsorbed on the surface of the shell 7b made of the metal oxide of the metal/metal oxide fine particle 7.

The metal oxide forming the shell 7b of the metal/metal oxide fine particles 7 includes, for example, titanium oxide (TiO₂), tin oxide (SnO₂), niobium oxide (Nb₂O₅), zinc oxide (ZnO) or the like. Of these metal oxides, TiO₂, especially anatase TiO₂, is preferred. It will be noted that the types of metal oxides are not limited to those and two or more metal oxides may be used in a mixed or composite form, if necessary. The metal/metal oxide fine particles may take any of particulate, tubular and rod-shaped forms.

The size of the metal/metal oxide fine particles 7 is not critical and is generally at 1 to 500 nm in terms of an average size of primary particles, preferably at 1 to 200 nm, and more preferably at 5 to 100 nm. The size of the core 7a of the metal/metal oxide fine particles 7 is generally at 1 to 200 nm.

In order to allow the dye 8 to be adsorbed as much as possible, the metal/metal oxide fine particles 7 should preferably have a great actual surface area including surfaces of the metal/metal oxide fine particles 7, which are facing with the pores inside the porous photoelectrode 3. To this end, the actual surface area in a state of the porous photoelectrode 3 formed on the transparent conductive film 2 should preferably be not less than 10 times the area (projected area) of an outer surface of the porous photoelectrode 3, more preferably not less than 100 times. Although no upper limit of this ratio is set, the limit is generally at about 1000 times.

As an electrolyte forming the electrolyte layer 6, there can be used an electrolytic solution or a gel or solid electrolyte. The electrolytic solution includes a solution containing a redox system (redox pair) and particularly, includes a combination of iodine I₂ and a metal or organic iodide salt, a combination of bromine Br₂ and a metal or organic bromide salt, and the like. The cations for metal salts include lithium (Li⁺), sodium (Na⁺), potassium (K⁺), cesium (Cs⁺), magnesium (Mg²⁺) , calcium (Ca²⁺) and the like. The cations for organic salts preferably include quaternary ammonium ions such as tetraalkylammonium ions, pyridinium ions and imidazolium ions, and these may be used singly or in admixture of two or more.

As an electrolyte for the electrolyte layer 6, there may be used, aside from those mentioned above, metal complexes such as a combination of a ferrocyanide salt and a ferricyanide salt, a combination of ferrocene and a ferricynium ion, and the like, sulfur compounds such as sodium polysulfide, a combination of an alkylthiol and an alkyl disulfide, a viologen dye, a combination of hydroquinone and quinone, and the like.

As the electrolyte for the electrolyte layer 6, it is preferred to use those electrolytes including combinations of iodine (I₂) and lithium iodide (LiI), sodium iodide (NaI) and quaternary ammonium compounds such as imidazolium iodide. The concentration of the electrolytic salt is preferably at 0.05M to 10M, more preferably at 0.2M to 3M, relative to solvent. The concentration of iodine I₂ or bromine Br₂ is preferably at 0.0005M to 1M, more preferably at 0.001. to 0.5M. For the purpose of improving an open voltage or a short-circuiting current, various additives such as 4-tert-butylpyridine and benzimidazolium compounds may be added.

The solvent for the electrolytic solution generally includes water, alcohols, ethers, esters, carbonate esters, lactones, carboxylic esters, phosphoric triesters, heterocyclic compounds, nitriles, ketones, amides, nitromethane, halogenated hydrocarbons, dimethyl sulfoxide, sulforane, N-methylpyrrolidone, 1,3-dimethylimidazolidinone, 3-methyloxazolidinone, hydrocarbons and the like.

In order to reduce the leakage of an electrolytic solution from a dye-sensitized photoelectric conversion device and the volatilization of a solvent of an electrolytic solution, a gelling agent, a polymer or a crosslinking monomer may be mixed with electrolytic components after dissolution or dispersion for use as a gel electrolyte. With respect to the ratio of the gelling material and the electrolytic components, if the electrolytic components are used in too large an amount, an ion conductivity increases, but mechanical strength lowers. In contrast, when the electrolytic components are used in too small an amount, mechanical strength becomes high, but ion conductivity lowers. Accordingly, the amount of the electrolytic components preferably ranges 50 wt % to 99 wt %, more preferably 80 wt % to 97 wt %, of the gel electrolyte. After mixing of an electrolyte and a plasticizer with a polymer, when the plasticizer is removed by evaporation, there can be realized a solid-state photosensitive photoelectric conversion device.

The transparent substrate 1 is not critical on the condition that its material and shape allow easy transmission of light, and various types of substrate materials may be used therefor. Especially, it is preferred to use a substrate material that has a high visible light transmittance. In addition, preferred materials are ones, which are high in blocking performance of inhibiting moisture and gases from entering from outside of a dye-sensitized photoelectric conversion device and are excellent in solvent and weather resistance. More particularly, as a material for the transparent substrate 1, mention is made of transparent inorganic materials such as quartz, glass and the like, and transparent plastics such as polyethylene terephthalate, polyethylene naphthalate, polycarbonate, polystyrene, polyethylene, polypropylene, polyphenylene sulfide, polyvinylidene fluoride, acetyl cellulose, phenoxy bromide, aramides, polyimides, polystyrenes, polyarylates, polysulfones, polyolefins and the like. The thickness of the transparent substrate 1 is not critical and can be appropriately chosen while taking into account light transmittance and the performance of internally and externally blocking a photoelectric conversion device.

The transparent conductive film 2 formed on the transparent substrate 1 should preferably have a sheet resistance that is as small as possible. More specifically, it is preferably at not larger than 500 Ω/□, more preferably at not larger than 100 Ω/□. The materials used to form the transparent conductive film 2 include known ones and are chosen as necessary. Specific examples of the material forming the transparent conductive film 2 include indium-tin composite oxide (ITO), fluorine-doped tin (IV) oxide SnO₂ (FTO), tin (IV) oxide SnO₂, zinc (II) oxide ZnO, indium-zinc composite oxide (IZO) and the like. It will be noted that the materials forming the transparent conductive film 2 are not limited thereto, and combinations of two or more thereof may also be used.

Although the dye 8 to be adsorbed on the porous photoelectrode 3 is not critical in so far as they exhibit sensitization action, those having an acid functional group, which allows adsorption on the surface of the shell 7b of the metal oxide of the metal/metal oxide fine particles 7 constituting the porous photoelectrode 3, are preferred. More particularly, the dye 8 preferably includes ones having a carboxyl group, a phosphate group or the like. Of these, ones having a carboxyl group are more preferred. Specific examples of the dye 8 include xanthene dyes such as Rhodamine B, Rose bengal, eosin, erythrosine and the like, cyanine dyes such as merocyanine, quinocyanine, kryptocyanine and the like, basic dyes such as phenosafranine, cabri blue, thiocine, methylene blue and the like, porphyrin compounds such as chlorophyll, zinc porphyrin, magnesium porphyrin and the like. Besides, mention is made of azo dyes, phthalocyanine compounds, coumarin compounds, bipyridine complex compounds, anthraquinone dyes, polycyclic quinone dyes and the like. Of these, metal complex dyes, which contain a pyridine ring or imidazolinium ring as a ligand (ligand) and at least one metal selected from the group including Ru, Os, Ir, Pt, Co, Fe and Cu, are preferred because of their high quantum yield. Especially, dye molecules having a fundamental skeleton of cis-bis(isothiocyanate)-N,N-bis(2,2′-dipyridyl-4,4′-dicarboxylic acid)-ruthenium(II) or tris(isothiocyanate)-ruthenium(II)-2,2′:6′,2″-terpyridine-4,4′,4″-tricarboxylic acid are preferred because of their wide absorption wavelength region. The dye 8 is not limited to those mentioned above. Typically, one of the above dyes is used as the dye 8, and two or more thereof may be mixed for use as the dye 8.

Although the manner of adsorbing the dye 8 on the porous photoelectrode 3 is not critical, the above dye is dissolved in a solvent such, for example, as alcohols, nitriles, nitromethane, halogenated hydrocarbons, ethers, dimethyl sulfoxide, amides, N-methylpyrrolidone, 1,3-dimethylimidazolidinone, 3-methyloxazolidinone, esters, carbonate esters, ketones, hydrocarbons, water or the like, and the porous photoelectrode 3 is immersed therein, or the resulting dye solution is coated onto the porous photoelectrode 3. For the purpose of reducing mutual association of the molecules of the dye 8, deoxycholic acid may be added. If necessary, UV absorbers may be used in combination.

To expedite removal of the dye 8 adsorbed in excess after the adsorption of the dye 8 on the porous photoelectrode 3, amines may be used to treat the surface of the porous photoelectrode 3. Examples of the amines include pyridine, 4-tert-butylpyrdine, polyvinyl pyridine and the like. If these are liquid in nature, they may be used as they are or may be used after dissolution in organic solvents.

Although the materials for the counter electrode 4 may be arbitrary ones so far as they are conductive materials, there may be used one wherein a conductive layer is formed on an insulating material at a facing side of the electrolyte layer 6. The material for the counter electrode 4 used is preferably an electrochemically stable one. Specifically, it is preferred to use platinum, gold, carbon and a conductive polymer.

In order to improve the catalytic action against reduction reaction at the counter electrode 4, the counter electrode 4 is preferably formed with a fine structure on the surface in contact with the electrolyte layer 6 so as to increase an actual surface area. For instance, it is preferred that with platinum, it is formed in a state of platinum black and with carbon, it is formed in a state of porous carbon. Platinum black can be formed by the anodization method or chloroplatinic acid treatment of platinum and porous carbon can be formed by sintering of carbon fine particles or firing of organic polymer.

The counter electrode 4 is formed on a transparent conductive film formed on one main surface of a counter substrate, if necessary, although not limited thereto. As a counter substrate material, there may be used opaque glass, plastics, ceramics, metals and the like, or transparent materials including, for example, transparent glass or plastics. The transparent conductive film used may be similar to the transparent conductive film 2.

The material for the sealant 5 is preferably one having light fastness, insulating property and moisture proofness. Specific examples of the material for the sealant 5 include epoxy resins, UV curable resins, acrylic resins, polyisobutylene resin, EVA (ethylene-vinyl acetate), ionomer resins, ceramics, various types of thermally fusible films and the like.

Where a solution of an electrolyte composition is charged, an injection port is needed. The injection port is not critical with respect to its location in so far as it is not disposed on the porous photoelectrode 3 and the counter electrode 4 at a portion facing therewith. Although the manner of charging a solution of an electrolyte composition is not critical, it is preferred to use a method wherein the outer periphery is preliminarily sealed and the solution is charged, under reduced pressure, into the photoelectric conversion device that has a solution injection port opened. In this case, a method of dropping several droplets of the solution at the injection port and charging the solution by capillary phenomenon is simple. If necessary, the operation of charging the solution may be effected under reduced pressure or heating. After complete charge of the solution, the solution left at the injection port is removed and the injection port is sealed. The manner of the sealing is not critical and, if necessary, a glass or plastic sheet can be attached by use of a sealant and sealed. Aside from this method, sealing is possible by dropping an electrolytic solution on the substrates and bonding together under reduced pressure as in the step of one-drop filling (ODF) of liquid crystal of a liquid crystal panel. In addition, with a gel electrolyte or solid-state electrolyte making use of polymers or the like, a polymer solution containing an electrolyte composition and a plasticizer is cast on the porous photoelectrode 3, followed by removal by volatilization. After complete removal of the plasticizer, sealing is carried out in a manner as set out above. This sealing is preferably conducted by use of a vacuum sealer in an atmosphere of an inert gas or under reduced pressure. After completion of the sealing, heating or compressing operations may be effected, if necessary, so as to permit the electrolyte to be well impregnated into the porous photoelectrode 3.

### [Method for Making the Dye-Sensitized Photoelectric Conversion Device]

Next, the method of making this dye-sensitized photoelectric conversion device is illustrated.

Initially, the transparent conductive film 2 is formed on one main surface of the transparent substrate 1 such as by a sputtering technique.

Next, the porous photoelectrode 3 made of the metal/metal oxide fine particles 7 is formed on the transparent conductive film 2. Although the manner of forming the porous photoelectrode 3 is not critical, a wet film-forming method is preferred when taking physical properties, convenience and manufacturing costs into consideration. In the wet film-forming method, it is preferred that a paste dispersion wherein a powder or sol of the metal/metal oxide fine particles 7 is uniformly dispersed in a solvent such as water is prepared, and this dispersion is coated or printed on the transparent conductive film 2 of the transparent substrate 1. The manner of coating or printing the dispersion is not critical and any known methods may be used therefor. More particularly, the coating method includes, for example, a dipping method, a spraying method, a wire bar method, a spin coating method, a roller coating method, a blade coating method, a gravure coating method and the like. Usable printing methods include a letterpress printing method, an offset printing method, a gravure printing method, an intaglio printing method, a rubber plate printing method, a screen printing method and the like.

The porous photoelectrode 3 should preferably be fired after coating or printing of the metal/metal oxide fine particles 7 on the transparent conductive film 2 so as to electrically, mutually connect the metal/metal oxide fine particles 7, improve mechanical strength of the porous photoelectrode 3 and improve adhesion with the transparent conductive film 2. The range of the firing temperature is not critical. If the temperature is raised in excess, the transparent conductive film 2 becomes high in electric resistance and may be molten in some case, for which it is preferably at 40 to 700° C., more preferably at 40 to 650° C. The firing time is not critical as well and is generally at about 10 minutes to 10 hours.

After the firing, for the purposes of increasing the surface area of the metal/metal oxide fine particles 7 and enhancing the necking between the metal/metal oxide fine particles 7, there may be carried out a dipping treatment, for example, with a titanium tetrachloride aqueous solution or a sol of titanium oxide ultrafine particles having a diameter of not larger than 10 nm. In case where a plastic substrate is used as the transparent substrate 1 supporting the transparent conductive film 2, it is possible to form a porous photoelectrode 3 in the form of a film on the transparent conductive film 2 by use of a paste dispersion containing a binder and subject to pressure bonding with the transparent conductive film 2 by means of a thermal press.

Next, the transparent substrate 1 formed with the porous photoelectrode 3 is immersed in a dye solution wherein the dye 8 is dissolved in a given type of solvent to allow the dye 8 to be adsorbed on the porous photoelectrode 3.

On the other hand, a counter electrode 4 is formed, for example, on a counter substrate such as by a sputtering technique.

Next, the transparent substrate 1 formed with the porous photoelectrode 3 and the counter electrode 4 are so disposed that the porous photoelectrode 3 and the counter electrode 4 are set in face-to-face relation at a given distance, for example, of 1 to 100 μm, preferably 1 to 50 μm. The sealant 5 is formed along the outer periphery of the transparent substrate 1 and the counter electrode 4 to establish a space in which an electrolyte layer is included. The electrolyte layer 6 is charged into the space from an injection port (not shown) formed in the transparent substrate 1 beforehand. Thereafter, the injection port is closed.

In this way, an intended dye-sensitized photoelectric conversion device is made.

The metal/metal oxide fine particles 7 for the porous photoelectrode 3 can be prepared according to conventional known methods (see, for example, Non-patent Document 3). For an example, the outline of a method of making metal/metal oxide fine particles 7 including the core 7a made of Au and the shell 7b made of TiO₂ is just as illustrated below. More particularly, anhydrous trisodium citrate is initially admixed with 500 ml of a heated solution of 5×10⁻⁴ M of HAuCl₄ and agitated. Next, 2.5 wt % of mercaptoundecanoic acid is added to an ammonia aqueous solution and agitated, followed by addition to a dispersion of Au nanoparticles and heat retention for two hours. Thereafter, 1M HCl is added so that the pH of the solution is adjusted to 3. Next, titanium isopropoxide and triethanolamine are added to the Au colloidal solution in an atmosphere of nitrogen. In this manner, there are prepared metal/metal oxide fine particles 7 each including a core 7a made of Au and a shell 7b made of TiO₂.

### [Operations of the Dye-Sensitized Photoelectric Conversion Device]

Next, the operations of this dye-sensitized photoelectric conversion device are illustrated.

When light falls on, the dye-sensitized photoelectric conversion device works as a cell wherein the counter electrode 4 serves as a positive electrode and the transparent conductive film 2 serves as a negative electrode. The principle is just as follows. It is assumed herein that FTO is used as a material for the transparent conductive film 2, the material for the core 7a of the metal/metal oxide fine particles 7 for the porous photoelectrode 3 is Au and the material for the shell 7b is TiO₂, and a redox species of I⁻/I₃⁻ is used as a redox pair although not limited thereto.

When the dye 8 adsorbed on the porous photoelectrode 3 absorbs photons that pass through the transparent substrate 1 and transparent conductive film 2 and enter into the porous photoelectrode 3, the electrons in the dye 8 are excited from the ground state (HOMO) to the excited state (LUMO). The thus excited electrons are withdrawn through electric coupling between the dye 8 and the porous photoelectrode 3 toward the conduction band of TiO₂ serving as the shell 7b of the metal/metal oxide fine particles 7 constituting the porous photoelectrode 3 and arrive at the transparent conductive film 2 through the porous photoelectrode 3. Additionally, light entry on the surface of the core 7a made of Au of the metal/metal oxide fine particles 7 causes a local surface plasmon to be excited, thereby obtaining a filed reinforcing effect. This reinforced electric field causes electrons to be excited in large quantity in the conduction band of TiO₂ serving as the shell 7b, and the electrons arrive at the transparent conductive film 2 via the porous photoelectrode 3. In this way, when light enters into the porous photoelectrode 3, not only the electrons generated by the excitation of the dye 8 arrive at the transparent conductive film 2, but also the electrons excited in the conduction band of TiO₂ used as the shell 7b as a result of the excitation of the local surface plasmon in the surface of the core 7a of the metal/metal oxide fine particles 7 arrive thereat. Thus, there can be obtained a high photoelectric conversion efficiency.

On the other hand, the dyes losing the electrons receives electrons from a reductant, e.g. I⁻, in the electrolyte layer 6 according to the following reaction, thereby forming an oxidizer, e.g. I₃⁻ (a combined matter of I₂ and in the electrolyte layer 6.

2I⁻→I₂+2e⁻

I₂+I⁻→I₃⁻

The oxidizer formed in this way arrives at the counter electrode 4 by diffusion, receives electrons from the counter electrode 4 through a reverse reaction of the above reaction and is reduced into an original reductant.

I₃⁻→I₂+I⁻

I₂+2e⁻−2I⁻

The electrons transmitted from the transparent conductive film 2 toward an external circuit electrically work at the external circuit and are returned to the counter electrode 4. Thus, light energy is converted into electric energy without suffering a change in either the dye 8 or the electrolyte layer 6.

As having stated hereinabove, according to this first embodiment of the invention, the porous photoelectrode 3 is constituted of the metal/metal oxide fine particles 7 having a core/shell structure, which includes the spherical core 7a made of a metal and the shell 7b surrounding the core 7a and made of a metal oxide. In this arrangement, when the electrolyte layer 6 is filled between the porous photoelectrode 3 and the counter electrode 4, the electrolyte in the electrolyte layer 6 is not in contact with the core 7a made of a metal for the metal/metal oxide fine particles 7, so that the porous photoelectrode 3 is prevented from dissolving with the electrolyte. Thus, as the metal of the core 7a of the metal/metal oxide fine particles 7, there can be used gold, silver, copper or the like, which has a great surface plasmon resonance effect, thereby ensuring a satisfactory surface plasmon resonance effect. Moreover, an iodine-based electrolyte can be used as an electrolyte of the electrolyte layer 6. Gathering the foregoing, there can be obtained a dye-sensitized photoelectric conversion device whose photoelectric conversion efficiency is high. Using this excellent dye-sensitized photoelectric conversion device, high-performance electronic devices can be realized.

### <2. Second Embodiment>

### [Dye-Sensitized Photoelectric Conversion Device]

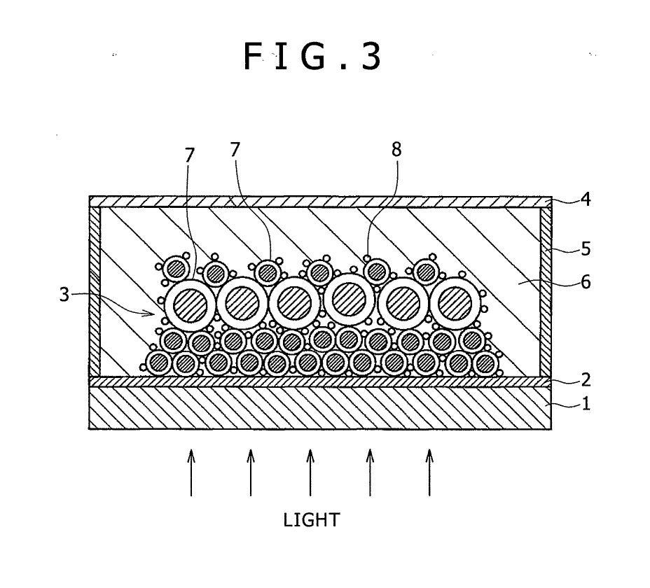

As shown in FIG. 3, in the dye-sensitized photoelectric conversion device according to the second embodiment, the metal/metal oxide fine particles 7 for the porous photoelectrode 3 are of the types that have particle sizes different from each other. In this case, in addition to the metal/metal oxide fine particles 7 having the same particle size as the metal/metal oxide fine particles 7 constituting the porous photoelectrode 3 in the dye-sensitized photoelectric conversion device of the first embodiment, metal/metal oxide fine particles 7 having a larger size are further contained. The larger-sized metal/metal oxide fine particles 7 have a scattering effect of light entering into the porous photoelectrode 3 and also a light-confining effect. Additionally, because the larger-sized metal/metal oxide fine particles 7 have an absorption wavelength different from that of the smaller-sized metal/metal oxide fine particles 7 and thus, a wavelength region of light that can be utilized for photoelectric conversion can be extended. The size of the larger-sized metal/metal oxide fine particles 7 is preferably at 20 to 500 nm, for example, although not limited thereto.

### [Method for Making the Dye-Sensitized Photoelectric Conversion Device]

The method of making this dye-sensitized photoelectric conversion device is similar to the case of the dye-sensitized photoelectric conversion device according to the first embodiment except that two types of fine particles having different sizes are used as the metal/metal oxide fine particles 7 of the porous photoelectrode 3.

According to the second embodiment, similar merits as in the first embodiment can be obtained.

### <3. Third Embodiment>

### [Dye-Sensitized Photoelectric Conversion Device]

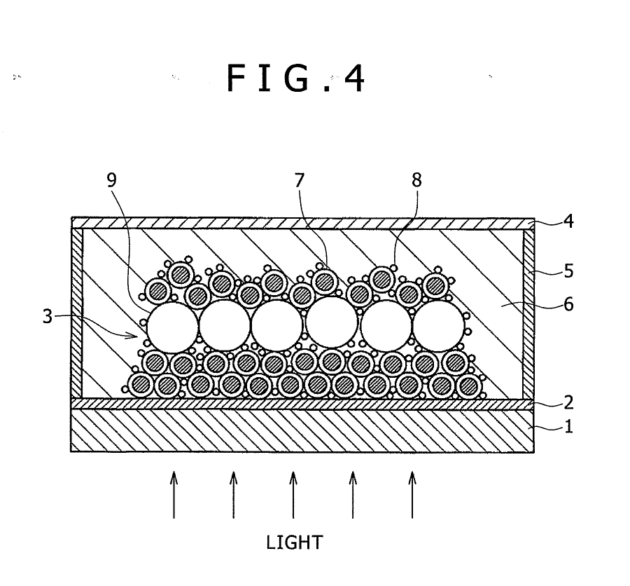

As shown in FIG. 4, in the dye-sensitized photoelectric conversion device according to the third embodiment, the porous photoelectrode 3 is constituted of the metal/metal oxide fine particles 7 and spherical scattering particles 9 having a larger size than that of the metal/metal oxide fine particles 7. The metal/metal oxide fine particles 7 have a size same as the metal/metal oxide fine particles 7 constituting the porous photoelectrode 3 in the dye-sensitized photoelectric conversion device according to the first embodiment. The scattering particles 9 are made of a metal oxide such as TiO₂. The larger-sized scattering particles 9 have a scattering effect of light entering into the porous photoelectrode 3 and also a light-confining effect. The particle size of the scattering particles 9 is preferably at 20 to 500 nm, for example, although not limited thereto.

### [Method for Making the Dye-Sensitized Photoelectric Conversion Device]

The method of making this dye-sensitized photoelectric conversion device is similar to the case of the dye-sensitized photoelectric conversion device according to the first embodiment except that the porous photoelectrode 3 is formed of the metal/metal oxide fine particles 7 and the scattering particles 9.

According to the third embodiment, similar merits as in the first embodiment can be obtained.

### <4. Fourth Embodiment>

### [Dye-Sensitized Photoelectric Conversion Device]

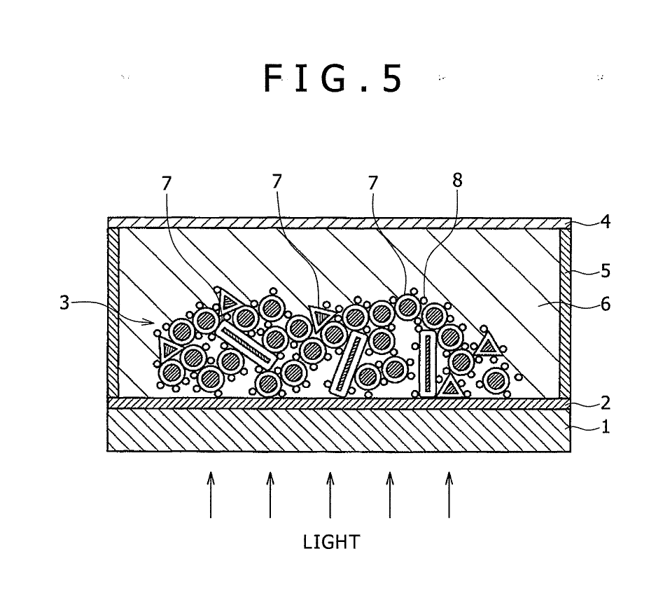

As shown in FIG. 5, in the dye-sensitized photoelectric conversion device according to the fourth embodiment, as metal/metal oxide fine particles 7 constituting the porous photoelectrode 3, those fine particles having different shapes are mixed with each other.

More particularly, the porous photoelectrode 3 is formed, for example, of spherical metal/metal oxide fine particles 7, rod-shaped metal/metal oxide fine particles 7, tetrahedral metal/metal oxide fine particles 7 and the like. The absorption wavelengths of the metal/metal oxide fine particles 7 having mutually difference shapes differ from each other and thus, the wavelength region of light capable of being utilized for photoelectric conversion can be extended, thereby ensuring an improved photoelectric conversion efficiency.

### [Method for Making the Dye-Sensitized Photoelectric Conversion Device]

The method of making this dye-sensitized photoelectric conversion device is similar to the case of the dye-sensitized photoelectric conversion device according to the first embodiment except that the porous photoelectrode 3 is formed of the metal/metal oxide fine particles 7 having different shapes.

According to the fourth embodiment, similar merits as in the first embodiment can be obtained.

### <5. Fifth Embodiment>

### [Dye-Sensitized Photoelectric Conversion Device]

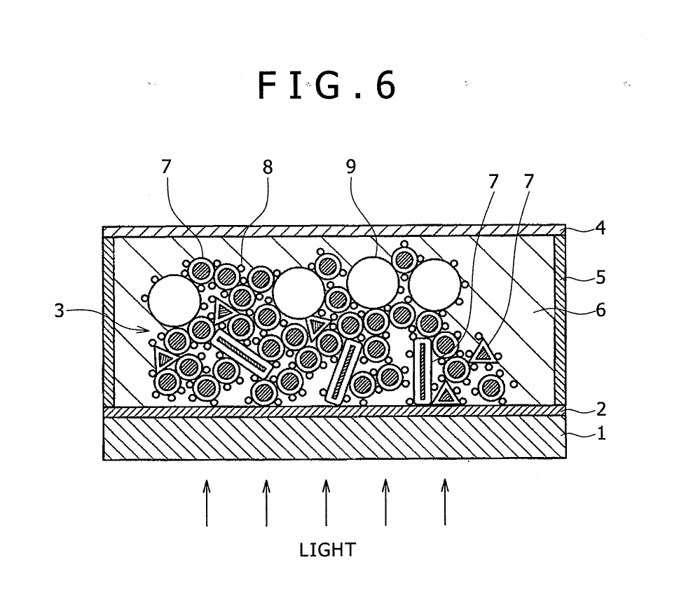

As shown in FIG. 6, in the dye-sensitized photoelectric conversion device according to the fifth embodiment, the porous photoelectrode 3 is formed of the metal/metal oxide fine particles 7 of the types having different shapes with each other as used in the fourth embodiment and scattering particles 9 as used in the third embodiment. The scattering particles 9 have a scattering effect of light entering into the porous photoelectrode 3 and also a light-confining effect. Additionally, since the metal/metal oxide fine particles 7 of the types whose shapes differ from each other have different absorption wavelengths and thus, a wavelength region of light capable of being utilized for photoelectric conversion is extended, thereby ensuring an improved photoelectric conversion efficiency.

### [Method for Making the Dye-Sensitized Photoelectric Conversion Device]

The method of making this dye-sensitized photoelectric conversion device is similar to the case of the dye-sensitized photoelectric conversion device according to the first embodiment except that the porous photoelectrode 3 is formed of the metal/metal oxide fine particles 7 of the types having different shapes and the scattering particles 9.

According to the fifth embodiment, similar merits as in the first embodiment can be obtained.

### <6. Sixth Embodiment>

### [Dye-Sensitized Photoelectric Conversion Device]

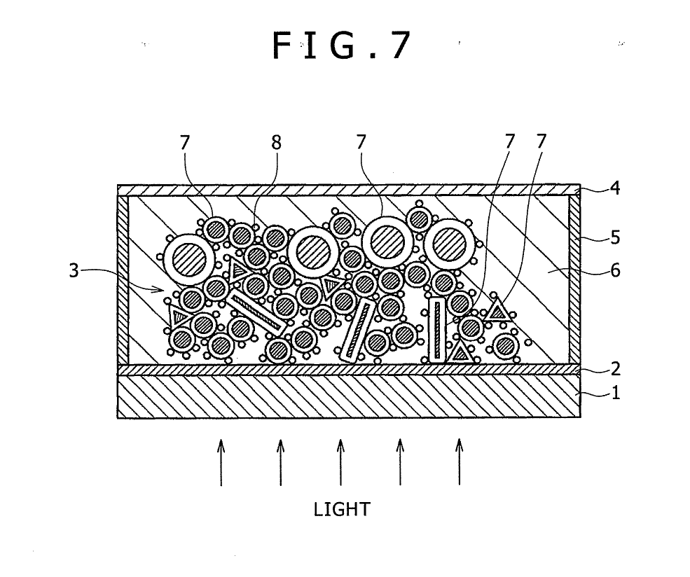

As shown in FIG. 7, in the dye-sensitized photoelectric conversion device according to the sixth embodiment, the porous photoelectrode 3 is formed of the metal/metal oxide fine particles 7 of the types having different shapes with each other as in the fourth embodiment and spherical metal/metal oxide fine particles 7 having a larger size than the former metal/metal oxide fine particles 7. The larger-sized metal/metal oxide fine particles 7 have a scattering effect of light entering into the porous photoelectrode 3 and also a light-confining effect. Additionally, since the metal/metal oxide fine particles 7 of the types whose shapes differ from each other have different absorption wavelengths and thus, a wavelength region of light capable of being utilized for photoelectric conversion is extended, thereby ensuring an improved photoelectric conversion efficiency.

### [Method for Making The Dye-Sensitized Photoelectric Conversion Device]

The method of making this dye-sensitized photoelectric conversion device is similar to the case of the dye-sensitized photoelectric conversion device according to the first embodiment except that the porous photoelectrode 3 is formed of the metal/metal oxide fine particles 7 of the types having different shapes and the larger-sized spherical metal/metal oxide fine particles 7.

According to the sixth embodiment, similar merits as in the first embodiment can be obtained.

### <7. Seventh Embodiment>

### [Photoelectric Conversion Device]

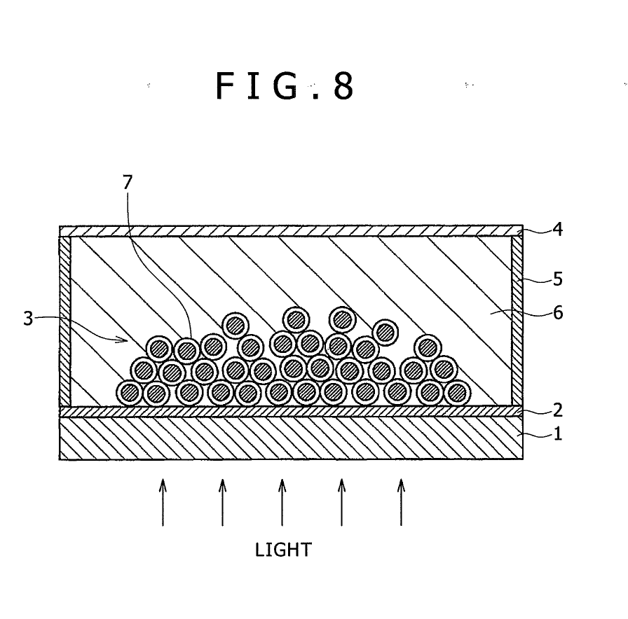

As shown in FIG. 8, the photoelectric conversion device according to the seventh embodiment has a similar configuration as the dye-sensitized photoelectric conversion device of the first embodiment except that no dye 8 is adsorbed on the metal/metal oxide fine particles 7 constituting the porous photoelectrode 3.

### [Method for Making a Photoelectric Conversion Device]

The method of making this photoelectric conversion device is similar to the case of the dye-sensitized photoelectric conversion device according to the first embodiment except that no dye 8 is adsorbed on the porous photoelectrode 3.

### [Operations of the Photoelectric Conversion Device]

Now, the operations of this photoelectric conversion device are illustrated.

When light enters into the this photoelectric conversion device, the device works as a cell wherein the counter electrode 4 serves as a positive electrode and the transparent conductive film 2 serves as a negative electrode. This principle is just as follows. It is assumed herein that FTO is used as a material for the transparent conductive film 2, the material for the core 7a of the metal/metal oxide fine particles 7 for the porous photoelectrode 3 is Au and the material for the shell 7b is TiO₂, and a redox species of I⁻/I₃⁻ is used as a redox pair although not limited thereto.

When light passes the transparent substrate 1 and the transparent conductive film 2 and enters into the surface of the core 7a made of Au of the metal/metal oxide fine particles 7 constituting the porous photoelectrode 3, a local surface plasmon is excited, thereby obtaining a filed reinforcing effect. This reinforced electric field allows electrons to be excited in large quantity in the conduction band of TiO₂ serving as the shell 7b, and electrons arrive at the transparent conductive film 2 via the porous photoelectrode 3.

On the other hand, the porous photoelectrode 3 losing the electrons receives electrons from a reductant, e.g. I⁻, in the electrolyte layer 6 according to the following reaction, thereby forming an oxidizer, e.g. I₃⁻ (a combined matter of I₂ and I⁻), in the electrolyte layer 6.

2I⁻→I₂+2e⁻

I₂+I⁻→I₃⁻

The oxidizer formed in this way arrives at the counter electrode 4 by diffusion, receives electrons from the counter electrode 4 through a reverse reaction of the above reaction and is reduced into an original reductant.

I₃⁻→I₂+I⁻

I₂+2e⁻→2I⁻

The electrons transmitted from the transparent conductive film 2 toward an external circuit electrically work at the external circuit and are returned to the counter electrode 4. Thus, light energy is converted into electric energy without suffering a change in either the dye 8 or the electrolyte layer 6.

According to the seventh embodiment, merits as in the first embodiment can be obtained.

### <8. Eighth Embodiment>

### [Photoelectric Conversion Device]

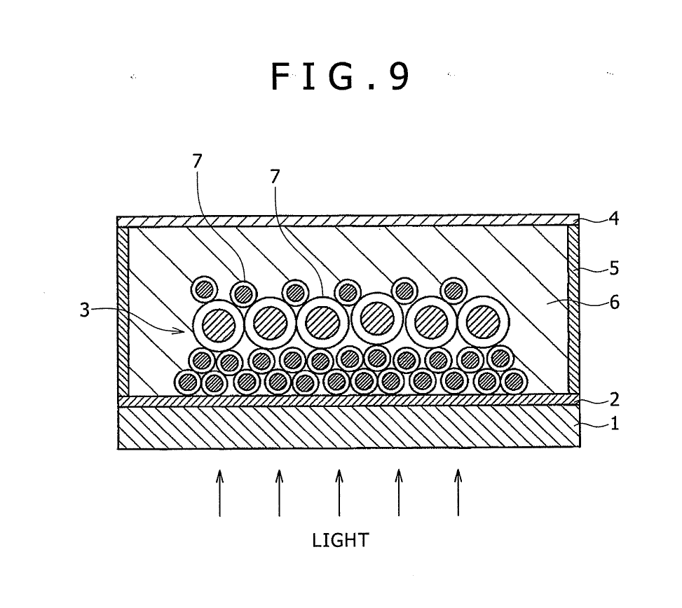

As shown in FIG. 9, the photoelectric conversion device according to the eighth embodiment has a similar configuration as the dye-sensitized photoelectric conversion device of the second embodiment except that no dye 8 is adsorbed on the metal/metal oxide fine particles 7 constituting the porous photoelectrode 3.

### [Method for Making a Photoelectric Conversion Device]

The method of making this photoelectric conversion device is similar to the case of the dye-sensitized photoelectric conversion device according to the first embodiment except that no dye 8 is adsorbed on the porous photoelectrode 3.

According to the eighth embodiment, merits as in the first embodiment can be obtained.

### <9. Ninth Embodiment>

### [Photoelectric Conversion Device]

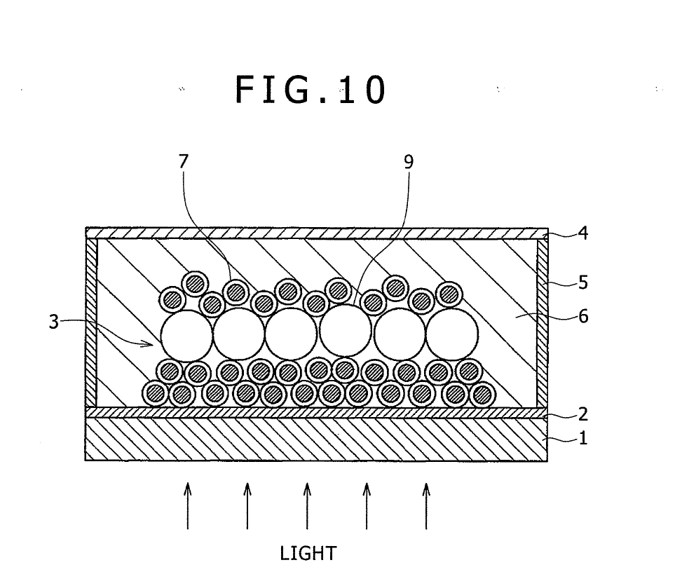

As shown in FIG. 10, the photoelectric conversion device according to the ninth embodiment has a similar configuration as the dye-sensitized photoelectric conversion device of the third embodiment except that no dye 8 is adsorbed on the metal/metal oxide fine particles 7 and the scattering particles 9, both constituting the porous photoelectrode 3.

### [Method for Making a Photoelectric Conversion Device]

The method of making this photoelectric conversion device is similar to the case of the dye-sensitized photoelectric conversion device according to the first embodiment except that no dye 8 is adsorbed on the porous photoelectrode 3.

According to the ninth embodiment, merits as in the first embodiment can be obtained.

### <10. Tenth Embodiment>

### [Photoelectric Conversion Device]

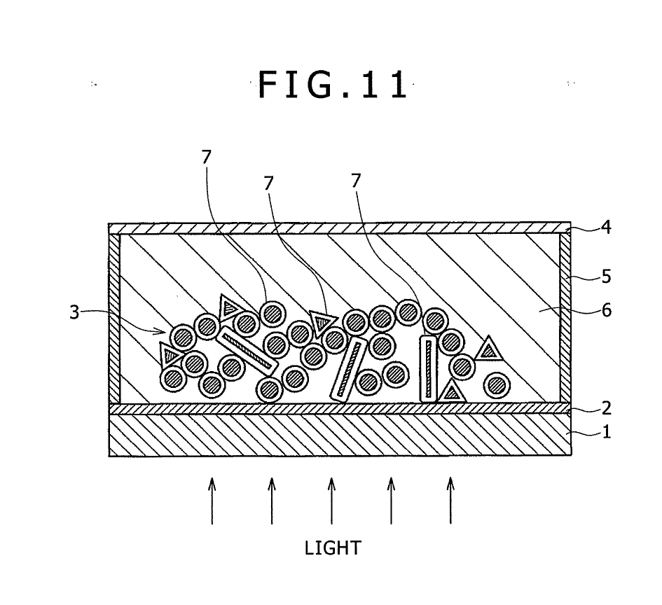

As shown in FIG. 11, the photoelectric conversion device according to the tenth embodiment has a similar configuration as the dye-sensitized photoelectric conversion device of the fourth embodiment except that no dye 8 is adsorbed on the metal/metal oxide fine particles 7 constituting the porous photoelectrode 3.

[Method for Making a Photoelectric Conversion Device]

The method of making this photoelectric conversion device is similar to the case of the dye-sensitized photoelectric conversion device according to the first embodiment except that no dye 8 is adsorbed on the porous photoelectrode 3.

According to the tenth embodiment, merits as in the first embodiment can be obtained.

### <11. Eleventh Embodiment>

### [Photoelectric Conversion Device]

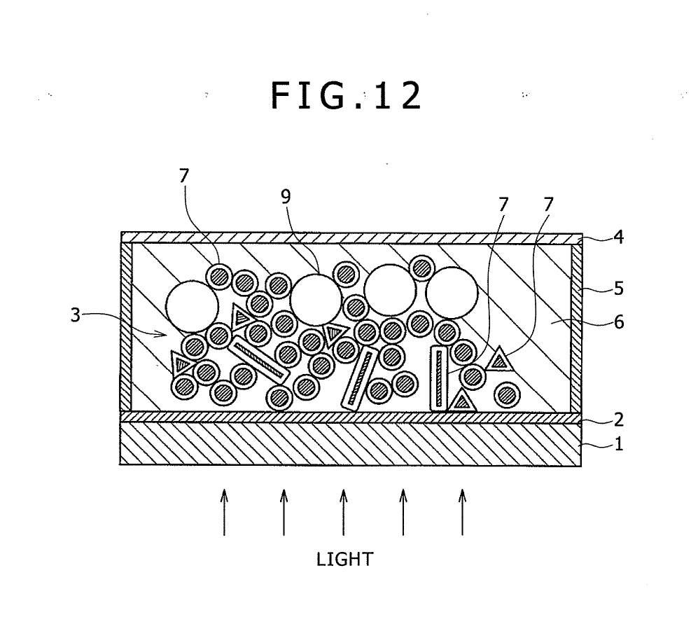

As shown in FIG. 12, the photoelectric conversion device according to the eleventh embodiment has a similar configuration as the dye-sensitized photoelectric conversion device of the fifth embodiment except that no dye 8 is adsorbed on the metal/metal oxide fine particles 7 and the scattering particles 9, constituting the porous photoelectrode 3.

### [Method for Making a Photoelectric Conversion Device]

The method of making this photoelectric conversion device is similar to the case of the dye-sensitized photoelectric conversion device according to the first embodiment except that no dye 8 is adsorbed on the porous photoelectrode 3.

According to the eleventh embodiment, merits as in the first embodiment can be obtained.

<12. Twelfth embodiment>

### [Photoelectric Conversion Device]

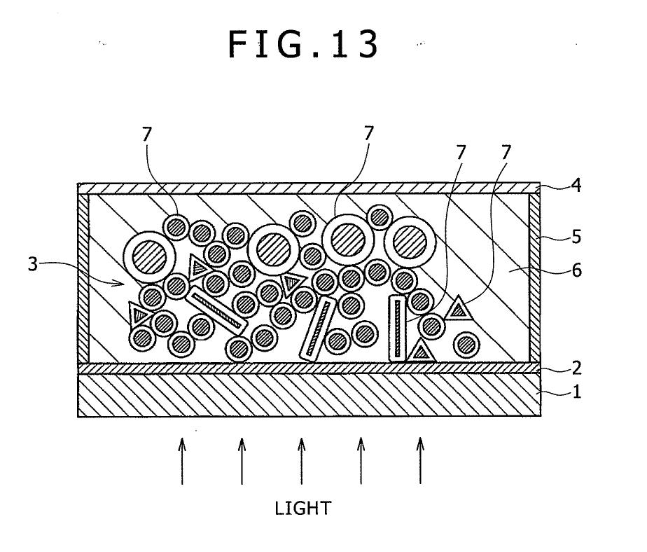

As shown in FIG. 13, the photoelectric conversion device according to the twelfth embodiment has a similar configuration as the dye-sensitized photoelectric conversion device of the sixth embodiment except that no dye 8 is adsorbed on the metal/metal oxide fine particles 7 constituting the porous photoelectrode 3.

### [Method for Making a Photoelectric Conversion Device]

The method of making this photoelectric conversion device is similar to the case of the dye-sensitized photoelectric conversion device according to the first embodiment except that no dye 8 is adsorbed on the porous photoelectrode 3.

According to the twelfth embodiment, merits as in the first embodiment can be obtained.

### <13. Thirteenth Embodiment>

### [Dye-Sensitized Photoelectric Conversion Device]

In the dye-sensitized photoelectric conversion device according to the thirteenth embodiment, Z907 and dye A, both serving as the dye 8, are adsorbed on and bound to, in different steric configurations, the surface of the shell 7b made of the metal oxide of the metal/metal oxide fine particles 7 constituting the porous photoelectrode 3. 3-Methoxypropionitrile (MPN) is contained in the electrolyte layer 6 as a solvent. Other configurations are similar to the dye-sensitized photoelectric conversion device shown in FIG. 1.

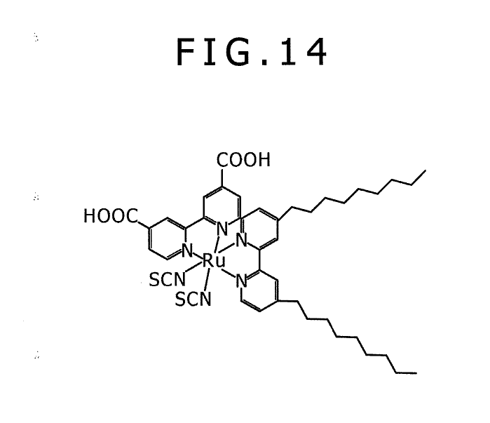

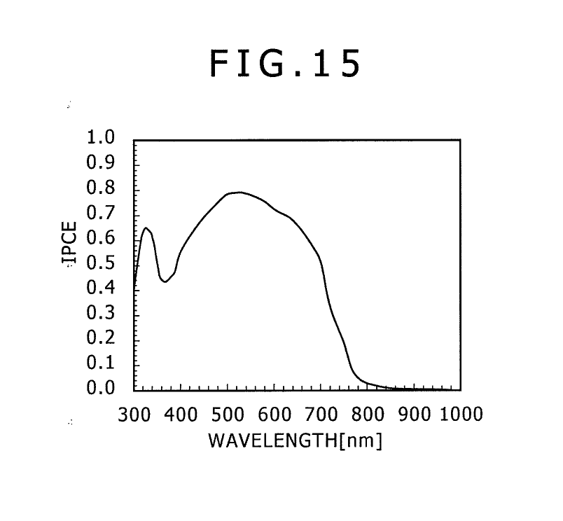

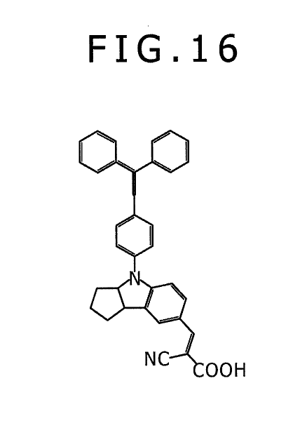

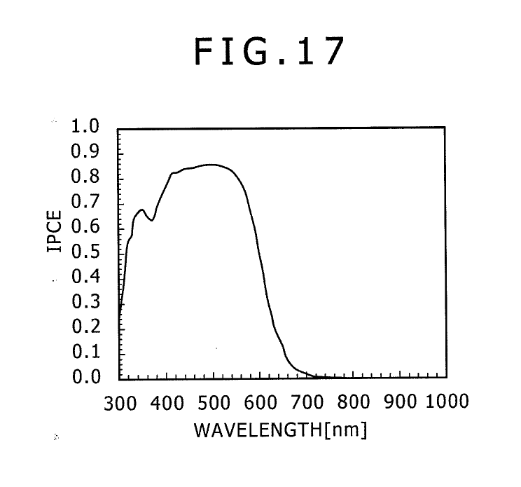

FIG. 14 shows a structural formula of Z907. In FIG. 15, there are shown the results of measurement of IPCE (Incident Photon-to-current Conversion Efficiency) spectra when Z907 is adsorbed singly on the surface of the porous TiO₂ photoelectrode. FIG. 16 shows a structural formula of dye A and FIG. 17 shows the results of measurement of IPCE spectra when the dye A is adsorbed singly on the surface of the porous TiO₂ photoelectrode. As shown in FIGS. 15 and 17, although Z907 is able to absorb light within a wide range of wavelength, there is a region of a small absorbance in a short wavelength region. In this short wavelength region, the dye A having a great absorbance in the short wavelength region is in a complementary relation with respect to light absorption. More particularly, the dye A acts as a sensitizing dye having a great absorbance in this short wavelength region.

As shown in FIG. 14, Z907 has a carboxy group (−COOH) as a functional group strongly bound to the porous photoelectrode 3 and thus, the carboxy group binds to the porous photoelectrode 3. On the other hand, as shown in FIG. 16, the dye A has a carboxy group (—COOH) serving as a functional group strongly bound to the porous photoelectrode 3 and a cyano group (—CN) serving as a functional group weakly bound to the porous photoelectrode 3, both groups being bound to the same carbon thereof. With the dye A, the carboxy group and the cyano group, bound to the same carbon, are bound to the porous photoelectrode 3. More particularly, the dye A adsorbs on the porous photoelectrode 3 by means of the carboxy group and the cyano group, both bound to the same carbon and this adsorption on the porous photoelectrode 3 is made in a steric configuration differing from that of Z907 adsorbed on the porous photoelectrode 3 only by the carboxy group. If a plurality of functional groups bound to the same carbon of the dye A are all those functional groups strongly bound to the porous photoelectrode 3, the steric configuration of the dye A absorbed on the porous photoelectrode 3 is reduced in degree of freedom, thus leading to the unlikelihood of developing an effect of the existence of a plurality of the functional groups absorbed on the porous photoelectrode 3. In contrast, with the dye A, the cyano group weakly bound to the porous photoelectrode 3 complementarily functions without impeding the strong bonding of the carboxy group to the porous photoelectrode 3. As a consequence, with the dye A, the effects of the carboxy group and the cyano group bound to the same carbon develop efficiently. More particularly, if the dye A and Z907 exist adjacently on the surface of the porous photoelectrode 3, they can co-exist without affecting strong interaction therebetween, for which mutual photoelectric conversion performances cannot be impeded. On the other hand, the dye A is able to effectively intervene among the molecules of Z907 bound to the same surface of the porous photoelectrode 3, thereby acting to suppress association of Z907 and preventing wasteful electron transfer between the Z907 molecules. Accordingly, the excited electrons of the Z907 having absorbed light are efficiently taken out to the porous photoelectrode 3 without wasteful transfer between the Z907 molecules, thereby ensuring an improved photoelectric conversion efficiency of Z907. The excited electrons of the light-absorbed dye A are taken out from the strongly bound carboxy group to the porous photoelectrode 3, so that charge transfer to the porous photoelectrode 3 is efficiently carried out.

### [Method for Making the Dye-Sensitized Photoelectric Conversion Device]

The method of making this dye-sensitized photoelectric conversion device is similar to the case of the dye-sensitized photoelectric conversion device of the first embodiment except that Z907 and dye A are adsorbed on the porous photoelectrode 3 as the dye 8.

### [Operations of the Dye-Sensitized Photoelectric Conversion Device]

Next, the operations of this dye-sensitized photoelectric conversion device are illustrated.

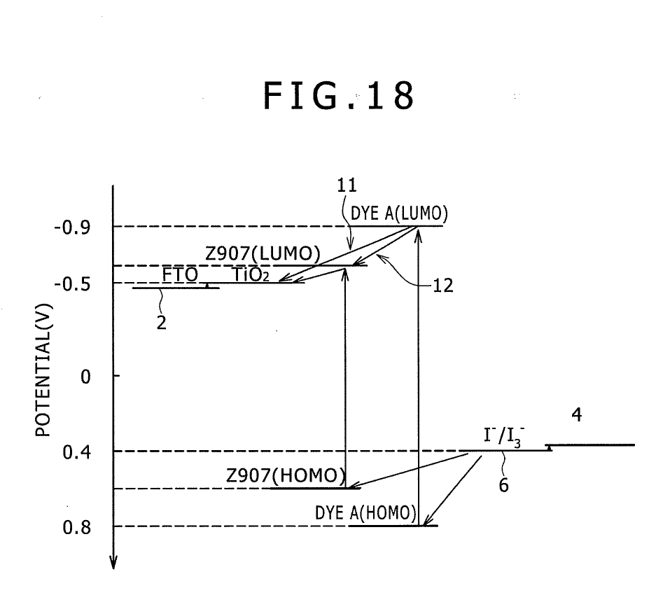

FIG. 18 is an energy diagram illustrating the operation principle of the dye-sensitized photoelectric conversion device. When light falls on, this dye-sensitized photoelectric conversion device works as a cell wherein the counter electrode 4 serves as a positive electrode and the transparent conductive film 2 serves as a negative electrode. The principle is just as follows. It is assumed herein that FTO is used as a material for the transparent conductive film 2, the material for the core 7a of the metal/metal oxide fine particles 7 for the porous photoelectrode 3 is Au and the material for the shell 7b is TiO₂, and a redox species of I⁻/I₃⁻ is used as a redox pair although not limited thereto.

When the dye 8, i.e. Z907 and dye A, adsorbed on the porous photoelectrode 3 absorbs photons that pass through the transparent substrate 1 and transparent conductive film 2, electrons in the Z907 and dye A are excited from the ground state (HOMO) to the excited state (LUMO). Since the dye 8 is made of Z907 and dye A, the dye 8 is able to absorb light of a wider wavelength range at a higher optical absorbance than with the case of existing dye-sensitized photoelectric conversion devices making use of a single dye.

The electrons of the excited state are withdrawn through electric coupling between the dye 8, i.e. Z907 and dye A, and the porous photoelectrode 3 toward the conduction band of TiO₂ serving as the shell 7b of the metal/metal oxide fine particles 7 constituting the porous photoelectrode 3 and arrive at the transparent conductive film 2 through the porous photoelectrode 3. At this stage, the minimum excitation energies of Z907 and dye A, i.e. HOMO-LUNO gaps, significantly differ from each other and these Z907 and dye A absorb, in different configurations, on the surface of the shell 7b of the metal/metal oxide fine particles 7 of the porous photoelectrode 3, so that wasteful electron transfer between the Z907 and the dye A is unlikely to occur. Accordingly, these Z907 and dye A do not lower mutual quantum yields and the photoelectric conversion performance based on the Z907 and dye A develops, thereby drastically improving an electric current generation. In this system, the electrons in the excited state of the dye A are withdrawn to the conduction band of the shell 7b of the metal/metal oxide fine particles 7 for the porous photoelectrode 3 through two routes. One is a direct route 11 wherein the excited electrons of the dye A is withdrawn directly to the conduction band of the shell 7b of the metal/metal oxide fine particles 7 constituting the porous photoelectrode 3. The other is an indirect route 12 wherein the excited electron of the dye A are withdrawn to an excited state of Z907 that is low in energy level and subsequently withdrawn from the excited state of the Z907 to the conduction band of the shell 7b of the metal/metal oxide fine particle 7 for the porous photoelectrode 3. The contribution of this indirect route 12 leads to an improved photoelectric conversion efficiency of the dye A wherein Z907 co-exists along with the dye A.

On the other hand, the Z907 and dye A losing the electrons receive electrons from a reductant, e.g. I⁻, in the electrolyte layer 6 according to the following reaction, thereby forming an oxidizer, e.g. I₃⁻ (a combined matter of I₂ and I⁻), in the electrolyte layer 6.

2I⁻→I₂+2e⁻

I₂+I⁻→I₃^{→}

The thus formed oxidizer arrives at the counter electrode 4 by diffusion, receives electrons from the counter electrode 4 through a reverse reaction of the above reaction and is reduced into an original reductant.

I₃⁻→I₂+I⁻

I₂+2e⁻→2I⁻

The electrons transmitted from the transparent conductive film 2 toward an external circuit electrically work at the external circuit and are returned to the counter electrode 4. Thus, light energy is converted into electric energy without suffering a change in either the dye 8, i.e. Z907 and dye A, or the electrolyte layer 6.

The effects were evaluated as obtained by adsorbing Z907 and dye A as the dye 8 on the surface of the shell 7b including TiO₂ of the metal/metal oxide fine particles 7 for the porous photoelectrode 3 and making use of 3-methoxypropylnitrile as a solvent of the electrolyte layer 6. In this evaluation test, however, a conventional porous photoelectrode made of TiO₂ fine particles was used in place of the porous photoelectrode 3 made of the metal/metal oxide fine particles 7. In either case where Z907 and dye A are adsorbed on the surface of the metal/metal oxide fine particles 7 or where Z907 and dye A are adsorbed on the surface of TiO₂ fine particles, Z907 and dye A are adsorbed on TiO₂ and electrons from the dye 8 are transferred to TiO₂. Thus, it is considered that if TiO₂ fine particles are used in place of metal/metal oxide fine particles 7, the effect obtained by adsorbing Z907 and dye A on the surface of the shell 7b made of TiO₂ of the metal/metal oxide fine particles 7 can be evaluated.

The dye-sensitized photoelectric conversion device used for the evaluation test was made in the following way.

A paste dispersion of TiO₂, which was a starting material for forming a porous photoelectrode made of TiO₂ fine particles was prepared by reference to “Newest Technology for Dye-Sensitized Solar Cells” (edited by Hironori Arakawa, 2001, CMC Publishing Co., Ltd.). More particularly, 125 ml of titanium isopropoxide was gradually dropped in 750 ml of a 0.1 M nitric acid aqueous solution at room temperature under agitation. After the dropping, the solution was transferred to a thermostatic bath at 80° C. and agitated over eight hours to obtain a clouded semi-transparent sol solution. This sol solution was allowed to cool down to room temperature and filtered by use of a glass filter, followed by addition of a solvent to make 700 ml of the solution. The resulting sol solution was transferred to an autoclave and subjected to hydrothermal reaction at 220° C. for 12 hours, followed by dispersion treatment by ultrasonic treatment for one hour. Next, the solution was concentrated by means of an evaporator at 40° C. so that the content of TiO2 was at 20 wt%. 20% of polyethylene glycol (molecular weight: 500,000) relative to the weight of TiO2 and 30% of anatase TiO₂ having a particle diameter of 200 nm and based on the weight of TiO₂ were added to the thus concentrated sol solution and uniformly mixed by means of an agitation defoaming machine to obtain a TiO₂ paste dispersion whose viscosity was increased.

The above TiO₂ paste dispersion was coated onto an FYO layer serving as a transparent conductive film 2 by a blade coating technique to form a fine-particle layer having a size of 5 mm×5 mm and a thickness of 200 μm, followed by keeping at 500° C. for 30 minutes to sinter the TiO₂ fine particles on the FTO layer. A 0.1 M titanium (IV) chloride TiCl₄ aqueous solution was dropped over the thus sintered TiO₂ film and kept at room temperature for 15 hours, washing and sintering at 500° C. for 30 minutes. Thereafter, UV light was irradiated over the TiO₂ sintered body by use of a ultraviolet irradiator and impurities, such as organic matters, present in the TiO₂ sintered body were removed by oxidative decomposition with the photocatalytic action of TiO₂ to enhance the activity of the TiO₂ sintered body, thereby obtaining a porous photoelectrode made of the TiO₂ fine particles.

For the dye 8, 23.8 mg of Z907 and 2.5 mg of dye A, both well purified, were dissolved in 50 ml of a mixed solvent of acetonitrile and tert-butanol at a ratio by volume of 1:1 (hereinafter referred to simply as mixed solvent of acetonitrile and tert-butanol) thereby preparing a dye solution.

Next, the porous photoelectrode was immersed in the dye solution at room temperature for 24 hours to permit Z907 and dye A serving as the dye 8 to be deposited on the surface of the TiO₂ fine particles. Subsequently, the porous photoelectrode was successively rinsed with an acetonitrile solution of 4-tert-butylpyridine and acetonitrile, followed by evaporating the solvent in the dark and drying.

The counter electrode 4 was formed by successively laminating, on the FTO layer wherein an injection port having a diameter of 0.5 mm had been formed beforehand, a 50 nm thick chromium layer and a 100 nm thick platinum layer, on which an isopropyl alcohol (2-propanol) solution of chloroplatinic acid was spray-coated and heated at 385° C. for 15 minutes.

Next, the transparent substrate 1 and the counter electrode 4 were so arranged that the porous photoelectrode and the counter electrode 4 were facing each other, and the outer periphery was sealed with a 30 μm thick ionomer resin film and an acrylic UV curing resin.

On the other hand, 10.030 g of sodium iodide NaI, 1.0 g of 1-propyl-2,3-dimethylimidazolium iodide, 0.10 g of iodine I₂, and 0.054 g of 4-tert-butylpyridine (TBP) were dissolved in 2.0 g of 3-methoxypropionitrile (solvent) to prepare an electrolytic solution.

This electrolytic solution was charged from the preliminarily arranged injection port of the dye-sensitized photoelectric conversion device by means of a feed pump and bubbles in the device was expelled under reduced pressure. In this way, the electrolyte layer 6 was formed. Next, the injection port was sealed with an ionomer resin film, an acrylic resin and a glass substrate to complete a dye-sensitized photoelectric conversion device for evaluation.

### Comparative Example 1

Acetonitrile was used as a solvent in place of 3-methoxypropionitrile to prepare an electrolytic solution. The others were same as the above dye-sensitized photoelectric conversion device for evaluation to make a dye-sensitized photoelectric conversion device.

### Comparative Example 2

Black dye (abbreviated as BD) and dye A were used in place of Z907 and dye A as a photosensitizing dye to be adsorbed on a porous photoelectrode. The others were same as the above dye-sensitized photoelectric conversion device for evaluation to make a dye-sensitized photoelectric conversion device.

### Comparative Example 3

Black dye (abbreviated as BD) and dye A were used in place of Z907 and dye A as a photosensitizing dye 8 to be adsorbed on a porous photoelectrode and acetonitrile was used as a solvent in place of 3-methoxypropionitrile to prepare an electrolytic solution. The others were same as the above dye-sensitized photoelectric conversion device for evaluation to make a dye-sensitized photoelectric conversion device.

### <Performance Evaluation of the Dye-Sensitized Photoelectric Conversion Device for Evaluation>

As to the thus made dye-sensitized photoelectric conversion device for evaluation, a photoelectric conversion efficiency in a current-voltage curve at the time of irradiation with pseudo solar light (AM 1.5, 100 mW/cm²) was measured. As a result, the photoelectric conversion efficiency of the dye-sensitized photoelectric conversion device for evaluation wherein Z907 and dye A were adsorbed on the porous photoelectrode made of TiO₂ fine particles was at 7.3%. This value of the photoelectric conversion efficiency is higher than a photoelectric conversion efficiency of 4.3% in case where dye A was bound singly to the porous photoelectrode and a photoelectric conversion efficiency of 6.6% in case where Z907 was bound singly to the porous photoelectrode 3.

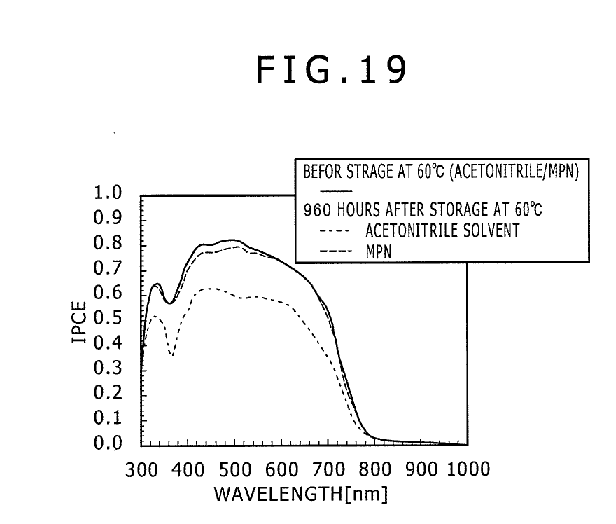

In order to confirm long-term reliability of the dye-sensitized photoelectric conversion device for evaluation within a short time, this dye-sensitized photoelectric conversion device was subjected to an accelerated degradation test wherein the device was kept in an environment of 60° C. over a long time (960 hours). The results are shown in FIG. 19. In FIG. 19, the results of the accelerated degradation test of the dye-sensitized photoelectric conversion devices for comparison are also shown. As shown in FIG. 19, with the dye-sensitized photoelectric conversion device of the comparative examples making use of acetonitrile as a solvent of the electrolyte layer 6, the IPCE is significantly reduced after the accelerated degradation test and thus, the photoelectric conversion performance significantly lowers. In contrast, with the dye-sensitized photoelectric conversion device for evaluation making use of 3-methoypropionitrile as a solvent of the electrolyte layer 6, there is little reduction in IPCE after the accelerated degradation test, with little change in photoelectric conversion performance.

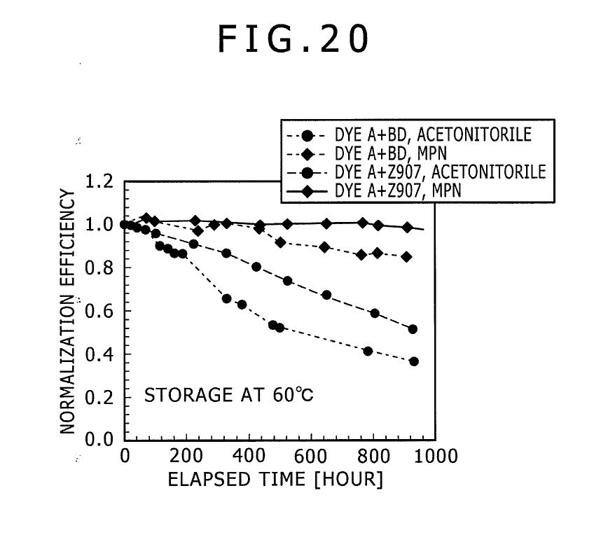

The dye-sensitized photoelectric conversion devices for evaluation and Comparative Examples 1 to 3 were kept in an environment of 60° C. to determine a change of photoelectric conversion efficiency with time. The results are shown in FIG. 20. The ordinate axis of FIG. 20 indicates a normalized one of photoelectric conversion efficiency (normalization efficiency) determined from the current-voltage measurement of the dye-sensitized photoelectric conversion device. As shown in FIG. 20, with the dye-sensitized photoelectric conversion devices of Comparative Examples 1 to 3, the photoelectric conversion efficiencies are significantly reduced with time, whereas the dye-sensitized photoelectric conversion device for evaluation suffers little change in the photoelectric conversion efficiency after a lapse of 960 hours. In view of this, it will be seen that the dye-sensitized photoelectric conversion device for evaluation is high in durability and excellent in long-term reliability. Thus it can be said that the dye-sensitized photoelectric conversion device of the thirteenth embodiment is also high in durability and excellent in long-term reliability.

As having stated hereinabove, according to the thirteenth embodiment of the invention, Z907 and dye A are used as the dye 8 to be adsorbed on the surface of the shell 7b of the metal/metal oxide fine particles 7 constituting the porous photoelectrode 3 and 3-methoxypropionitrile is used as a solvent for preparing the electrolyte layer 6. Hence, the photoelectric conversion efficiency is scarcely reduced as time passes and a dye-sensitized photoelectric conversion device having high durability and excellent long-term reliability can be obtained.

### <14. Fourteenth Embodiment>

### [Dye-sensitized Photoelectric Conversion Device]

In the dye-sensitized photoelectric conversion device of the fourteenth embodiment, a nanocomposite gel made of an electrolytic solution making use of 3-methoxypropionitrile as a solvent and nanoparticles made of TiO₂ or SiO₂. Other configurations of this dye-sensitized photoelectric conversion device are similar to the dye-sensitized photoelectric conversion device according to the thirteenth embodiment.

### [Method for Making the Dye-Sensitized Photoelectric Conversion Device]

The method of making the dye-sensitized photoelectric conversion device is same as with the dye-sensitized photoelectric conversion device of the thirteenth embodiment except that the electrolyte layer 6 is formed of a nanocomposite gel made of an electrolytic solution using 3-methoxypropionitrile as a solvent and nanoparticles made of TiO₂ or SiO₂.

The results of evaluation of the dye-sensitized photoelectric conversion device made in the same manner as in the thirteenth embodiment are illustrated.

The dye-sensitized photoelectric conversion device for evaluation was made in the following way.

3-Methoxypropionitrile was used as a solvent, to which such an electrolyte as used in the dye-sensitized photoelectric conversion device for evaluation in the thirteenth embodiment was added to prepare an electrolytic solution. About 10% of nanoparticles of SiO₂ was added to and mixed with the electrolytic solution and gelled to prepare a nanocomposite gel. This was used as the electrolyte layer 6. The others were same as the dye-sensitized photoelectric conversion device for evaluation made in the thirteenth embodiment, thereby providing a dye-sensitized photoelectric conversion device.

### <Performance Evaluation of the Dye-Sensitized Photoelectric Conversion Device for Evaluation>

The thus made dye-sensitized photoelectric conversion device for evaluation was subjected to measurement of a photoelectric conversion efficiency in a current-voltage curve at the time of irradiation of pseudo solar light (AM 1.5, 100 mW/cm²). As a result, it was found that the photoelectric conversion efficiency of the dye-sensitized photoelectric conversion device for evaluation wherein Z907 and dye A were bound to the surface of the TiO₂ fine particles for the porous photoelectrode was at 8.5%. This value of the photoelectric conversion efficiency is higher than a photoelectric conversion efficiency of 5.1% in case where dye A is bound singly to the surface of the TiO₂ fine particles constituting the porous photoelectrode and a photoelectric conversion efficiency of 7.5% in case where Z907 is bound singly to the surface of the TiO₂ fine particles for the porous photoelectrode.

According to the fourteenth embodiment, merits as in the thirteenth embodiment can be obtained.

The embodiments and examples of the invention have been particularly described and the invention should not be construed as limited to these embodiments and examples.

Various variations may be possible based on the technical concept of the invention.

For instance, the numerical values, structures, configurations, shapes and materials set forth in the embodiments and examples are only by way of examples and, if necessary, different numerical values, structures, configurations, shapes and materials may be used.

### EXPLANATION OF REFERENCE SYMBOLS

1 . . . Transparent substrate, 2 . . . Transparent conductive film, 3 . . . Porous photoelectrode, 4 . . . Counter electrode, 5 . . . Sealant, 6 . . . Electrolyte layer, 7 . . . Metal/metal oxide fine particles, 7a . . . Core, 7b . . . Shell, 8 . . . Dye, 9 . . . Scattering particles.

1. A photoelectric conversion device comprising a porous photoelectrode constituted of fine particles including a core of a metal and a shell surrounding the core and made of a metal oxide.

2. The photoelectric conversion device as defined in claim 1, wherein said metal is at least one metal selected from the group consisting of: gold, silver, copper, platinum and palladium.

3. The photoelectric conversion device as defined in claim 2, wherein said metal oxide is at least one metal oxide selected from the group consisting of: titanium oxide, tin oxide, niobium oxide and zinc oxide.

4. The photoelectric conversion device as defined in claim 3, wherein said fine particles have a size of 1 to 500 nm.

5. The photoelectric conversion device as defined in claim 4, wherein said core of said fine particles has a size of 1 to 200 nm.

6. The photoelectric conversion device as defined in claim 5, wherein a sensitizing dye is adsorbed on said porous photoelectrode.

7. The photoelectric conversion device as defined in claim 6, wherein said photoelectric conversion device is a dye-sensitized photoelectric conversion device having a structure wherein an electrolyte layer is filled between said porous photoelectrode and a counter electrode and the sensitizing dye is adsorbed on said porous photoelectrode.

8. The photoelectric conversion device as defined in claim 7, wherein Z907 and dye A are adsorbed on said porous photoelectrode as said sensitizing dye and 3-methoxypropionitrile is contained in said electrolyte layer as a solvent.

9. A method for making a photoelectric conversion device, the method comprising the step of
forming a porous photoelectrode from fine particles including a core made of a metal and a shell surrounding the core and made of a metal oxide.

10. The method for making a photoelectric conversion device as defined in claim 9, further comprising the steps of:
adsorbing Z907 and dye A on said porous photoelectrode as a sensitizing dye after the formation of said porous photoelectrode; and
forming a structure, wherein an electrolyte layer is filled between said porous photoelectrode and a counter electrode wherein 3-methoxypropionitrile is contained in said electrolyte layer as a solvent, after the adsorption of Z907 an dye A on said porous photoelectrode as a sensitizing dye.

11. An electronic device comprising a photoelectric conversion device, which has a porous electrode constituted of fine particles each made of a core made of a metal and a shell surrounding the core and made of metal oxide.
